(19) United States
(12) Patent Application Publication
(10) Pub. No.: US 2011/0079275 A1
(43) Pub. Date: Apr. 7, 2011

(54) SEMICONDUCTOR NANOPARTICLE/NANOFIBER COMPOSITE ELECTRODES

(75) Inventors: Qiquan Qiao, Brookings, SD (US); Prakash Joshi, Brookings, SD (US); Hao Fong, Rapid City, SD (US); David Galipeau, Brookings, SD (US); Lifeng Zhang, Rapid City, SD (US)

(73) Assignee: South Dakota State University

(21) Appl. No.: 12/896,860

(22) Filed: Oct. 2, 2010

Related U.S. Application Data
(60) Provisional application No. 61/248,178, filed on Oct. 2, 2009.

(51) Int. Cl. H01L 31/0264; C09K 11/67; B82Y 30/00

(52) U.S. Cl. 136/252; 252/301.4 R; 252/582; 977/773; 977/948

(57) ABSTRACT

Composite electrode materials for DSSCs, DSSCs incorporating the composite electrode materials and methods for making the composite electrode materials are provided. The composite electrode materials are composed of semiconductor nanofibers embedded in a matrix of semiconductor nanoparticles. DSSCs incorporating the composite electrode materials exhibit both increased carrier transport and improved light harvesting, particularly at wavelengths of 600 nm or greater (e.g., 600 nm to 800 nm or greater).

### CROSS-REFERENCE TO RELATED APPLICATIONS

This application claims priority to U.S. provisional patent application Ser. No. 61/248,178, filed on Oct. 2, 2009, the entire disclosure of which is incorporated herein by reference.

### STATEMENT REGARDING FEDERALLY SPONSORED RESEARCH OR DEVELOPMENT

This invention was made with United States Government Support awarded by the following agency: National Science Foundation (NSF) under grant number EPS-EPSCoR-0554609. The United States government has certain rights in this invention.

### FIELD OF THE INVENTION

The present invention relates to composite electrode materials comprising wide bandgap semiconductor nanoparticles and wide bandgap semiconductor nanofibers and to dye-sensitized solar cells incorporating the composite electrode materials.

### BACKGROUND OF THE INVENTION

Photovoltaic (PV) solar cells currently provide less than 0.1% of the world's energy needs and are only expected to meet about 2% of world needs in 20 years at an annual growth rate of 30%. This limited contribution is a result of the high cost of silicon (Si) solar cells ($2 to $4/watt) resulting from the need for high-purity silicon and high temperature processing. Almost 90% of the existing PV market is based on silicon cells. Unfortunately, after more than 50 years of development, further breakthroughs in Si PV appear unlikely.

Dye sensitized solar cells (DSSCs) are alternatives to traditional silicon solar cells. One typical DSSC consists of a porous TiO₂ nanoparticle photoelectrode and a platinum counter electrode separated by an iodide-triiodide liquid electrolyte. The nano-porous TiO₂ is sensitized by a dye, which serves as a light absorber. After photo-excitation, the dye molecules inject electrons into the TiO₂. The electrons then diffuse along the TiO₂ layer to the electrode and reach the counter electrode through an external circuit. The dye molecules then regain the lost electrons from the electrolyte.

DSSCs have drawn widespread interests since O'Regan and Gratzel used a cell incorporating a nanocrystalline TiO₂ nanoparticle film sensitized with a ruthenium complex dye in 1991. (See O'Regan, B.; Gratzel, M., A Low-Cost, High-Efficiency Solar-Cell Based on Dye-Sensitized Colloidal TiO₂ Films. Nature 1991, 353, 737-740.) Unfortunately, the efficiency of nanocrystalline TiO₂ nanoparticle-based DSSCs has been limited by the electron transport rate and inefficient light trapping in nanocrystalline TiO₂ films.

### BRIEF SUMMARY OF THE INVENTION

One aspect of the invention provides a composition comprising a matrix comprising a plurality of semiconductor nanoparticles and a plurality of semiconductor nanofibers dispersed in the nanoparticle matrix. The composite can further include a light absorbing material attached to at least some of the nanoparticles and nanofibers. In some embodiments of the composition, the average length for the nanofibers in the composition is at least 500 nm and the average diameter for the nanofibers in the composition is at least 200 nm.

Another aspect of the invention provides a dye-sensitized solar cell comprising a first electrode comprising a composite electrode material that includes a matrix comprising a plurality of semiconductor nanoparticles, a plurality of semiconductor nanofibers dispersed in the nanoparticle matrix and a light absorbing material attached to at least some of the semiconductor nanoparticles and semiconductor nanofibers. The solar cell further includes a second electrode and an electrolyte layer separating the first and second electrodes.

Yet another aspect of the invention provides a method of making a composite electrode material, the method comprising dispersing a plurality of semiconductor nanofibers in a paste comprising semiconductor nanoparticles to provide a composite paste, sintering the composite paste to provide a composite film and sensitizing the composite film with a light absorbing material. The semiconductor nanofibers in these methods are desirably made by electrospinning.

### BRIEF DESCRIPTION OF THE DRAWINGS

FIG. 1 shows (a) a scanning electron microscopy (SEM) image of an electrode material made of TiO₂ nanoparticles and (b) a corresponding electrode material made of a TiO₂ nanofiber/nanoparticle composite.

FIG. 2 shows the calculated correlation between the intensity of light scattering and the diameter of nanofiber: 200 nm (shortest set of arrows), 250 nm (mid-length set of arrows), and 300 nm (longest set of arrows). The length of arrows represents the intensity of scattered light. Incident light penetrates from the left side and is scattered to the right. Scattering from nanofibers having diameter of 100 is shown as a small black circle at the center of the grid.

FIG. 3 is a schematic diagram of a DSSC in accordance with the present invention.

FIG. 4 shows an SEM image of (a) non-ordered and (b) ordered TiO₂ nanofibers.

FIG. 5 shows an X-ray diffraction pattern of electrospun TiO₂ nanofibers.

FIG. 6(a) shows a high resolution transmission electron microscopy (HRTEM) image of an electrospun TiO₂ nanofiber; (b) shows an SEM image of a representative sample of electrospun TiO₂ nanofibers; and (c) shows a TEM image and the corresponding electron diffraction pattern (inset) indicating that the nanofibers comprising anatase-phase TiO₂ crystals with sizes of ˜10 nm.

FIG. 7 provides top view SEM images of photoanodes composed of (a) TiO₂ nanoparticles, (b) TiO₂ nanofibers, (c) a nanoparticle/nanofiber composite having a 15 wt. % nanofiber content, and (d) a nanoparticle/nanofiber composite having a 50 wt. % nanofiber content. FIG. 7 (e) shows a schematic of the nanofiber/nanoparticle composite (not to scale).

FIG. 8 shows current density-voltage (J-V) curves for one set of DSSCs (active cell areas are 0.087 cm² except for the call comprising 100% nanofibers; the cell comprising 100% nanofibers had an area of 0.27 cm²) with photoanodes fabricated from TiO₂ nanoparticle/nanofiber composites having a nanofiber content of 0%, 15%, 50%, and 100% by weight.

FIG. 9 (a) shows a comparison of the transmission spectra of TiO₂ nanoparticles alone (i.e., 0% nanofiber) for a film thickness of ˜7.5 μm, and a composite containing 15% nanofibers for film thicknesses of ˜5.5 μm and ˜7.5 μm; (b) shows a magnified version of the transmission spectrum for the composite containing 15% nanofibers for a film thickness of ˜7.5 μm. This shows that the transmission of visible and near infrared light was significantly reduced for a photoanode comprising 15% by weight of nanofibers with a diameter of 200-300 nm, relative to a photoanode comprising only nanoparticles, without any nanofibers.

FIG. 10 (a) shows the current density-voltage (J-V) curves for a second set of DSSCs (active cell area is 0.16 cm²) fabricated from nanofiber-nanoparticle samples with nanofiber percentages of 0, 15 and 100 wt. %; (b) shows the incident photon-to-electron conversion efficiencies (IPCE) for the DSSCs fabricated from nanofiber-nanoparticle samples with nanofiber percentages of 0, 15 and 100 wt. %.

### DETAILED DESCRIPTION

Composite electrode materials for DSSCs, DSSCs incorporating the composite electrode materials and methods for making the composite electrode materials are provided. The composite electrode materials are composed of semiconductor nanofibers embedded in a matrix of semiconductor nanoparticles. DSSCs incorporating the composite electrode materials exhibit both increased carrier transport and improved light harvesting, particularly at wavelengths of 600 nm or greater (e.g., 600 nm to 800 nm). The result is a substantial efficiency improvement over traditional DSSC technology based on photoanodes made from nanoparticles in the absence of nanofibers. This technology represents a significant improvement in device performance, including improved short circuit current, open circuit voltage and energy conversion efficiency. In addition, the cost of fabricating the solar cells can be substantially reduced relative to conventional DSSC cells because less material is needed to achieve comparable device performance.

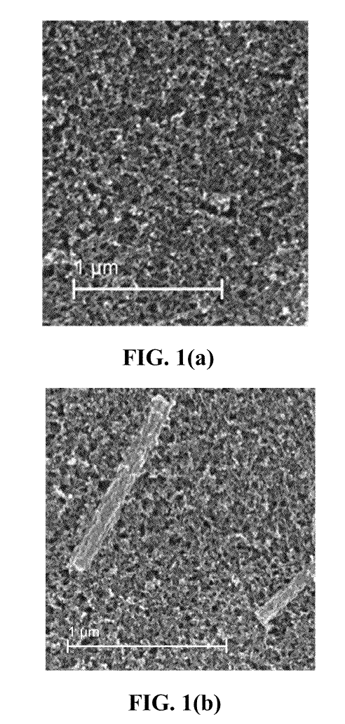

FIG. 1(b) shows a scanning electron microscope (SEM) image of one embodiment of a composite electrode material in accordance with the present invention. The electrode material in this embodiment is comprised of TiO₂ nanoparticles and polycrystalline TiO₂ nanofibers. For purposes of comparison, an SEM of a corresponding TiO₂ electrode comprising nanoparticles without nanofibers is shown in FIG. 1(a).

The nanofibers randomly embedded in the nanoparticle matrix significantly improve the light harvesting of the composite material by increasing the incident light path length via “Mie Scattering”. This forward light scattering generates a pattern similar to that of an antenna lobe, with the higher intensity of the forward lobe for nanofibers having relatively large diameters. As a result, DSSCs incorporating even thin layers of the present composite materials as electrodes are highly efficient. For example, a layer of the present composite electrode materials having a thickness no greater than 8 μm (e.g., ˜7.5 μm) can provide a DSSC having a conversion efficiency of at least 8%. This includes embodiments in which the layer of composite electrode material provides a DSSC having a conversion efficiency of at least 8.5% and further includes embodiments in which the layer of composite electrode material provides a DSSC having a conversion efficiency of at least 9%. Such improvements represent a 25%, 35% or even 45% increase in the conversion efficiencies of the present nanofiber/nanoparticle-based electrodes relative to electrodes made from nanoparticles alone.

The nanofibers in the present compositions scatter incident light effectively, resulting in a substantial improvement in light harvesting. The intensity of scattered light (I) in a nearby zone can be calculated using the following equation:

$$I = [ \frac{{I}_{0}}{r} {{π}^{2} ( m - 1 )}^{2} ] ( \frac{{a}^{2}}{λ} ) {\{ \frac{{J}_{1} [ ( \frac{4 π a}{λ} ) sin \frac{θ}{2} ]}{sin \frac{θ}{2}} \}}^{2} \qquad ( 1 )$$

where I₀ and λ are incident light intensity and wavelength, respectively; r is the distance from the nanofibers to the point being investigated, m is the refractive index of the nanofibers, a is the radius of the nanofibers, J₁ is the Bessel function, and θ is the angle between the directions of r and the incident light.

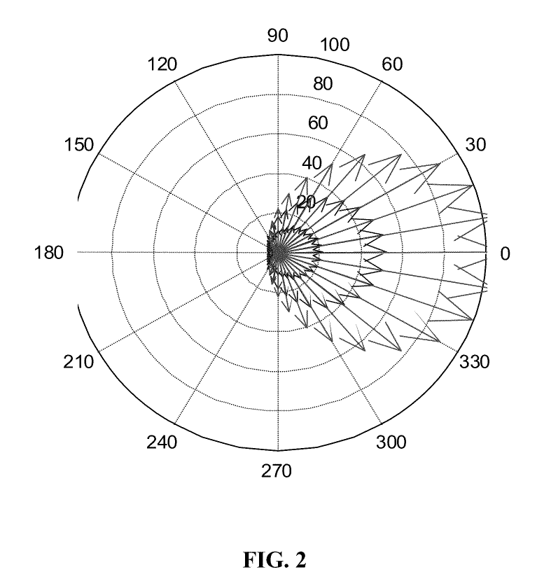

Using equation (1) under the assumption that the first term is an arbitrary constant and λ=570 nm (yellow light), the distribution of the scattered light vs. θ for different fiber diameters can be calculated (FIG. 2). The results show that the forward scattering increases with increasing nanofiber diameter, while the backward scattering is negligible regardless of fiber diameter. The intensity of the forward scattering for the nanofibers with diameters less than 200 nm is relatively weak; i.e., the scattered light is shown as a small black circle at the center in FIG. 2. However, when the diameters of the nanofibers increases to 200 nm or beyond, the light scattering becomes substantially stronger. This modeling provided theoretical guidance for selecting TiO₂ nanofibers with average diameters of at least about 200 nm (e.g., from 200 to 300 nm) for embodiments of the present DSSCs. Thus, in some embodiments of the present DSSCs, the average nanofiber diameter of the nanofibers in the matrix is at least 200 nm. This includes embodiments in which the average nanofiber diameter in the matrix is at least 250 nm. For example, in some embodiments the average diameter of the nanofibers in the compositions is in the range from 200 to 500 nm. This includes embodiments in which the average diameter of the nanofibers in the compositions is in the range from 200 to 300 nm. Such compositions can be achieved, for example, by using a collection of nanofibers wherein at least half of the nanofibers have diameters of at least 200 nm (e.g., diameters in the 200 to 300 nm range). This includes embodiments in which at least 80%, at least 90%, and at least 95% of the nanofibers have diameters of at least 200 nm. The compositions desirably include relatively few nanofibers having an average diameter of less than 100 nm. For example, in some embodiments the compositions comprising no greater than 20%, 10%, 5% or 1% nanofibers having an average diameter of less than 100 nm.

For purposes of this disclosure, the diameter of a nanofiber refers to its cross-sectional diameter. To the extent that the diameter of a nanofiber is not uniform about it circumference, its diameter shall be considered to be the average cross-sectional diameter about the circumference of the nanofiber.

Without intending to be bound to any particular theory of the invention, the inventors believe the improvements realized by the present composites can also be explained, at least in part, by the enhancement in electron transport rates and electron diffusion coefficients in the composites. Though a conventional nanoparticle film has a high surface area for efficient dye attachment, the grain boundaries between the crystals reduce the electron transport rate throughout the films. For example, the electron diffusion coefficients of electrospun TiO₂ nanowires have been measured to be orders of magnitude higher that of TiO₂ nanoparticle only films prepared under similar experimental conditions. (See P. S. Archana, R. Jose, C. Vijila, and S. Ramakrishna, Improved Electron Diffusion Coefficient in Electrospun TiO₂ Nanowires. Journal of Physical Chemistry C 2009, 113, 21538-21542). In addition, the diffusion coefficient of electron transport in a nanoparticle-based TiO₂ film has been reported to be two orders of magnitude less than that in a single anatase crystal TiO₂. (See Forro, L.; Chauvet, O.; Emin, D.; Zuppiroli, L.; Berger, H.; Levy, F., HIGH-MOBILITY N-TYPE CHARGE-CARRIERS IN LARGE SINGLE-CRYSTALS OF ANATASE (TIO₂). Journal of Applied Physics 1994, 75, (1), 633-635.) Typically a slow rate of electron percolation increases the possibility for the recombination of the electrons in TiO₂ and the tri-iodide in the electrolyte, thus reducing the DSSC energy conversion efficiency. Although the electron diffusion coefficients and lifetimes in one-dimensional (1D) materials, such as nanofibers, are much longer than those in nanoparticles, the energy conversion efficiencies of electrodes based on only 1D materials are limited since these materials do not possess a large surface area for enough dye attachment to achieve sufficient light absorption. For example, it was found that when only nanofibers (100% nanofibers) were used to make the photoanode the surface area for dye attachment decreased by 75.3% (Table 2), which was substantial, thereby leading to a lower solar cell performance for the photoanode made of only nanofibers relative to a photoanode made of only nanoparticles (0% nanofibers).

Thicker layers of the composite electrode materials can provide higher conversion efficiencies. For example, embodiments in which the layer of composite electrode material has a thickness of 10 μm or greater so that low energy photons (>800 nm) can be effectively scattered and harvested, and can provide a DSSC having a conversion efficiency of at least 10%. However, the optimal thickness will depend on the wavelength range of the incident light. Typical thicknesses for the composite electrode material layers are about 3 to about 20 μm. This includes composite electrode material layers having a thickness of about 5 to 15 μm and further includes composite electrode material layers having a thickness of about 6 to 10 μm. However, thicknesses outside these ranges may also be employed.

In one basic embodiment, the compositions that provide the composite electrode materials include a porous matrix comprising a plurality nanoparticles and a plurality of nanofibers dispersed in the nanoparticle matrix. The nanoparticles and nanofibers are both comprised of wide bandgap semiconductors, such as TiO₂, ZnO, CdSe, ZrO₂ or SnO₂ and the like. The nanoparticles and nanofibers can be doped or undoped.

In some embodiments, the porous nanoparticle matrix can comprise a composite of two or more wide bandgap semiconductors. For example, the matrix can include two or more different types of metal oxide semiconductor nanoparticles. If the nanoparticles are TiO₂ nanoparticles they can include nanoparticles having the anatase and/or rutile phase. However, the nanoparticles are desirably crystalline anatase-phase TiO₂ nanoparticles because such nanoparticles typically exhibit superior photovoltaic performance.

The nanoparticles may be nanocrystals having a spherical, or substantially spherical shape. However, the nanoparticles are not limited to nanocrystals having such shapes. For example, in some embodiments, the nanoparticles may be elongated (e.g., nanorods) or may have irregular shapes (e.g., nanoflowers). A nanoflower is a nanostructure which looks like flowers with a nanoscale dimension of lengths and thicknesses. Regardless of their shapes, the nanoparticles are characterized in that their longest cross-sectional dimension is no greater than about 100 nm. In some embodiments, the average longest cross-sectional dimension of the nanoparticles in a distribution of TiO₂ nanoparticles in the nanoparticle matrix is no greater than about 50 nm. This includes embodiments in which the average longest cross-sectional nanoparticle dimension in a distribution of nanoparticles in the nanoparticle matrix is no greater than about 20 nm, and further includes embodiments in which the average longest cross-sectional dimension in a distribution of nanoparticles in the nanoparticle matrix is no greater than 10 nm.

As discussed above, the nanofibers of the composite electrode materials are desirably sized to promote light harvesting through “Mie Scattering”. The nanofibers can be distinguished from nanowires and nanorods by their dimensions and mechanical flexibility. For the purposes of this disclosure, nanowires are defined as a nanostructure with a thickness or diameter of tens of nanometers or less (e.g., 50 nm or less) and an unrestricted length. Nanorods are elongated nanostructures in which each dimension ranges from 1-100 nm. Nanofibers, in contrast, are fibers with diameters of at least 100 nm and substantial or unconstrained lengths. The table below is a summary of the three types of nanostructures.

TABLE 1

| | | | Mechanical |
|---|---|---|---|
| | Diameter (nm) | Lengths (nm) | Flexibility |
| Nanowires | tens of nano- | Unrestricted, but longer | Sometimes |
| | meters or less | than the diameter | |
| Nanorods | 1-100 nm | 1-100 nm and longer than | No |
| | | the diameter | |
| Nanofibers | ≧100 nm | Unrestricted, but longer | Yes |
| | | than the diameter | |

The nanofibers can be made by a variety of known techniques. For example, TiO₂ nanofibers can be prepared by the technique of electrospinning using a solution of Titanium (IV) n-butoxide (TNBT) and polyvinylpyrrolidone (PVP) in anhydrous isopropanol (IPA) and dimethyl formamide (DMF), followed by pyrolysis at 500° C. Electrospinning is an innovative technique that uses electric force alone to drive the spinning process and to produce polymer, ceramic, and carbon/graphite nanofibers (See Dzenis, Y., Spinning Continuous Fibers for Nanotechnology. Science 2004, 304, 1917-1919; and Greiner, A, Wendorff, J., Electrospinning: a fascinating method for the preparation of ultrathin fibers. Angew. Chem. Int. Ed. 2007, 46, 5670-5703.). Unlike conventional spinning techniques (such as dry spinning, wet spinning, and melt spinning), which produce fibers with diameters in the micrometer range (e.g., 5-30 μm), electrospinning produces fibers with diameters in the range of 100s of nm. Electrospun nanofibers possess many extraordinary properties including small diameters and the large specific surface areas, a high degree of structural perfection and superior mechanical properties. Unlike nanowires, nanorods, and nanotubes, which are produced by synthetic, bottom-up methods, electrospun nanofibers are produced through a top-down nano-manufacturing process. This results in low-cost nanofibers that do not require further expensive purification and that are mechanically flexible and relatively easy to align, assemble, and process. Thus, in some embodiments, the average TiO₂ nanofiber length in a distribution of TiO₂ nanofibers ranges from nanometer scale to micro or millimeter scale. This includes embodiments in which the average TiO₂ nanofiber length in the distribution of TiO₂ nanofibers is at least 200 nm and further includes embodiments in which the average TiO₂ nanofiber length in the distribution of nanofibers is at least 500 nm, at least 1 μm, or at least 2 μm.

If the present compositions are to be used as electrodes in DSSCs, they further comprise a light absorbing material attached to at least a portion of the semiconductor nanoparticles, semiconductor nanofibers, or both. For the purposes of this disclosure, a light absorbing material may be any photoactive material capable of absorbing sufficient energy from photons to produce electrons which can be injected into the conduction band of the electrode material. Suitable light absorbing materials include organic dyes, photosensitive polymers and semiconductor nanocrystals (quantum dots). Various organic dyes suitable for use in DSSCs are known. These include, but are not limited to, cis-di(thiocyanato)bis(2,2′-bipyridyl-4,4′-dicarboxylate)ruthenium-(II) (also known as ruthenium 535-bisTBA or N719) and ruthenium 535.

The concentration of nanofibers in the composite electrode materials is desirably selected to provide enhanced carrier transport and light harvesting, without substantially sacrificing the surface area and dye loading of the composite materials. Thus, in some embodiments, the composite electrode materials comprise about 10 to about 20 weight percent nanofibers, based on the total combined weight of the nanoparticles and nanofibers. This includes embodiments in which the composite electrode materials comprise 12 to 18 weight percent nanofibers, based on the total combined weight of the nanoparticles and nanofibers, and further includes embodiments in which the composite electrode materials comprise 14 to 16 weight percent nanofibers, based on the total combined weight of the TiO₂ nanoparticles and TiO₂ nanofibers. However, acceptable energy conversion efficiencies are also achievable with a nanoparticle/nanofiber composite electrode where the concentration of nanofiber falls outside this range.

Ideally, the light absorbing material loading on a composite electrode material should differ only slightly from the loading on a corresponding ‘nanoparticle-only’ electrode. As used herein, the phrase ‘corresponding nanoparticle-only electrode’ refers to an electrode that differs in fabrication, construction and composition from a given nanoparticle/nanofiber composite electrode only in that the nanoparticle-only electrode includes only nanoparticles, rather than a mixture of the nanoparticles and nanofibers. The electrode materials of FIG. 1(b) and FIG. 1(a) show an example of a composite nanoparticle/nanofiber electrode and its corresponding nanoparticle-only electrode, respectively. In some embodiments of the present composite electrode materials, the dye loading on the composite electrode material differs by no more than 10 percent from the dye loading on the corresponding nanoparticle-only electrode. This includes embodiments in which the dye loading on the composite electrode material differs by no more than 8 percent from the dye loading on the corresponding nanoparticle-only electrode and further includes embodiments in which the dye loading on the composite electrode material differs by no more than 7 percent from the dye loading on the corresponding nanoparticle-only electrode.

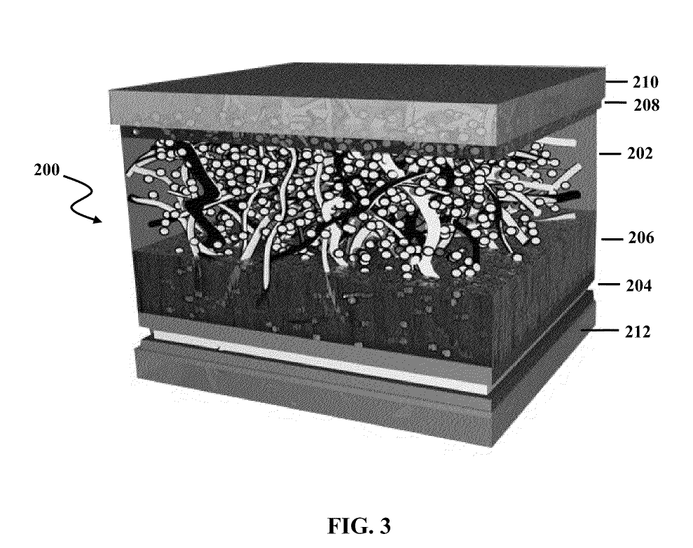

A basic DSSC 200 incorporating a composite electrode material as a first electrode 202 is shown in FIG. 3. As shown in the figure, the DSSC includes the first electrode 202 separated from a second electrode 204 (the counter electrode) by an electrolyte layer 206. The cell further includes a compact layer 208 and is housed between two transparent (e.g., FTO glass) substrates 210, 212.

The thickness of the first electrode can vary depending on the desired thickness of the DSSC and desired or optimized J-V characteristics of the cell. In some embodiments, the composite electrode material of the first electrode has a thickness of about 3 to 20 μm. This includes embodiments in which the composite electrode material of the first electrode has a thickness of about 5 to 15 μm and further includes embodiments in which the composite electrode material of the first electrode has a thickness of about 7 to 12 μm. In some embodiments, the composite electrode material of the DSSC is characterized in that a layer of the composite electrode material having a thickness of no greater than 8 μm can provide the DSSC with a cell efficiency of ˜9 percent. The efficiency of a DSSC incorporating the present composite electrode materials can be improved by utilizing thicker first electrodes. For example, DSSC having a cell efficiency above 9% may be fabricated by incorporating a composite electrode material having a thickness of 10 μM or greater to cause stronger light harvesting of low energy photons (photon wavelength larger than 800 nm).

The second electrode can be constructed from a variety of electrically conductive materials. By way of illustration only, the second electrode can be a metal-coated electrically conductive or porous nanocarbon based glass substrate, such as a platinum-coated and nanocarbon fluorine-doped tin dioxide (FTO) glass substrate.

The electrolyte layer can include a variety of electrolytes, as well as electrolyte additives and solvents. One example of a suitable electrolyte systems is the iodide-triiodide liquid electrolyte system. Electrolytes that may be present in such a system include I₂, LiI, 1-butyl-3-methylimidazolium iodide (BMII), and tetrabutylammonium iodide. In addition, the system can include one or more additives, such as guanidinium thiocyanate (GuSCN) and 4-tert-butylpyridine (TBP), as well as one or more solvents, such as acetonitrile and valeronitrile.

In addition to electrodes and photovoltaic cells incorporating the electrodes, the present invention provides methods for making the electrodes. In a basic method for making a nanoparticle/nanofiber composite electrode material, a plurality wide bandgap semiconductor nanofibers are dispersed in a paste comprising wide bandgap semiconductor nanoparticles. In addition to nanoparticles, the paste may include solvents and additives, such as processing aids. Ti-Nanoxide HT available from Solaronix is an example of a commercially-available nanoparticle paste for making a TiO₂-based electrode. Dispersion of the nanofibers in the paste can be facilitated, for example, using sonication. The resulting composite paste is then applied to a substrate. For example, the composite paste can be spread as a thin layer on an electrode substrate by doctor blading. The layer of composite materials is then sintered at elevated temperatures to provide a composite film. The sintering should be conducted under conditions under which aggregation of the nanoparticles and nanofibers is avoided, or substantially avoided. The composite film is then sensitized with an organic dye. Sensitization can be carried out by, for example, immersing the composite film in a solution comprising the dye and subsequently removing excess solution and dye. A detailed description of a method for making a DSSC incorporating a composite electrode material is provided in the Example, below.

### Example

In this example, electrospun TiO₂ nanofibers are dispersed in a matrix of TiO₂ nanoparticles to develop low-cost, highly efficient DSSCs. The results show that in addition to enhancing the electron transport, the nanofibers embedded in the nanoparticle matrix significantly improve the light harvesting by increasing the incident light path length via “Mie Scattering”.

### Experimental Details

The TiO₂ nanofibers were prepared by the technique of electrospinning using a solution of Titanium (IV) n-butoxide (TNBT) and polyvinylpyrrolidone (PVP) in anhydrous isopropanol (IPA) and dimethyl formamide (DMF). All the chemicals were purchased from the Sigma-Aldrich Co. and used without further purification.

A solution containing 10 wt. % TNBT and 10 wt. % PVP in IPA/DMF (mass ratio 1:1) with trace amount of HAc was first prepared at room temperature as the spin dope for making electrospun TNBT/PVP precursor nanofibers. HAc was added to the spin dope to control the hydrolysis/gelation of TNBT. The solution was then filled in a 30 ml BD Luer-Lok™ tip plastic syringe having an 18 gauge 90° blunt end stainless-steel needle. The electrospinning setup included a high voltage power supply (model number: ES30P), purchased from the Gamma High Voltage Research, Inc. (Ormond Beach, Fla.), and a laboratory-produced roller with a diameter of 10 inches. During electrospinning, a positive high voltage of 15 kV was applied to the needle; and the flow rate of 1.0 ml/h was maintained using a digitally controlled, positive displacement syringe pump (model number: KDS 200) purchased from the KD Scientific Inc. (Holliston, Mass.). TNBT/PVP precursor nanofibers were collected on the electrically grounded aluminum foil that covered the surface of the roller. The distance between the tip of the needle and the edge of the roller was set at 8 inches, and the rotational speed of the roller was set at 100 rpm during electrospinning. The as-electrospun TNBT/PVP precursor nanofiber mat was kept under ambient conditions (˜20° C. and ˜50% relative humidity) for a week to allow the TNBT in the nanofibers to completely hydrolyze and turn into a three dimensional network (gel).

A high-temperature pyrolysis was carried out to burn the organic components from the precursor nanofibers. The precursor nanofibers were carefully peeled off from the aluminum foil, transferred into a ceramic boat, and placed in a Lindberg 54453 Heavy Duty Tube Furnace purchased from the TPS Co. (Watertown, Wis.) for pyrolysis into the final TiO₂ nanofibers. The procedure for pyrolysis included (1) increasing the temperature at a rate of 10° C. per minute from the room temperature to 500° C., (2) maintaining the temperature at 500° C. for 6 hours to completely burn/remove the organic components in the fibers and to allow TiO₂ to crystallize, and (3) naturally cooling off to the room temperature. A constant flow of air was maintained through the furnace during the pyrolysis.

A nanocrystalline TiO₂ paste (Ti-Nanoxide HT) was purchased from Solaronix. The surface area of the film was ˜160 m²/g with an average nanoparticle size of ˜9 nm. In order to prepare TiO₂ nanofiber/nanoparticle composites, the nanofibers were first dispersed in anhydrous ethanol using a sonicator. The nanofibers were then mixed with the nanoparticle paste and the mixture was again sonicated to disperse the nanofibers in the matrix of the nanocrystalline TiO₂ paste. Finally, the mixtures were heat-treated at 450° C. for 1 hour to obtain the composites. Composites having 0% 15%, 50%, and 100% nanofibers by weight were prepared. Fluorine-doped tin dioxide (FTO) glass substrates (Hartford Glass Co. TEC-8, sheet resistance of ˜8Ω/□, FTO thickness of ˜400 nm and the glass thickness of 2.3 mm) were cleaned using a sonicator with detergent solution, de-ionized (DI) water, acetone and IPA in succession, and then treated with oxygen plasma for 10 minutes.

The photoanodes were prepared by applying the composites on the FTO substrate, which was precoated with a thin compact layer of 0.2 M titanium di-isopropoxide bis(acetylacetonate), by doctor blading. The thicknesses of the films were controlled by varying the tape thickness and composite viscosity.

The photoanodes were sintered at 100° C. for 30 minutes and then 450° C. for another 45 minutes. The TiO₂ composites were then treated with TiCl₄ and sintered again as above. The photoanodes were then soaked in a 0.5 mM solution of N719 dye in a mixed solution of acetonitrile and tert-butyl alcohol with 1:1 volume ratio at room temperature for 48 hours. The counter electrodes were prepared by sputtering platinum onto the FTO glass substrates. The electrolyte was a redox couple I⁻/I₃⁻ containing 0.60M BM II, 0.03M I₂, 0.10M GuSCN, 0.5 M tert-butylpyridin in a mixed solvent of acetonitrile and valeronitrile (85:15 volume ratio).

A Zeiss Supra 40VP field-emission scanning electron microscope (SEM) and a Rigaku Ultima Plus X-ray diffraction (XRD) system, as well as a Hitachi HF-3300 transmission electron microscope/scanning transmission electron microscope (TEM/STEM), were employed to characterize the morphological and structural properties of both the as-electrospun precursor nanofibers and the resulting final TiO₂ nanofibers. Prior to SEM examination, the specimens were sputter-coated with gold to avoid charge accumulations. A rotating X-ray generator (40 kW, 40 mA) with CuKa radiation (wavelength λ=1.54 Å) was used in the XRD experiments. The XRD profiles were recorded from 20° to 60° at a scanning speed of 2° min⁻¹. For the high-resolution TEM characterizations, an acceleration voltage of 100 kV was selected for the precursor nanofibers and an acceleration voltage of 300 kV was selected for the final TiO₂ nanofibers. The TEM specimens were prepared by dispersing fibers onto lacey carbon films supported on 200-mesh copper grids.

The DSSC devices were tested for energy conversion efficiency under illumination by a solar simulator and for external quantum efficiency (EQE) under a calibrated monochromator. The energy conversion efficiency was measured under ambient conditions using an Agilent 4155C Source Generator by sourcing the voltage from 0 to +1 V in 0.01V steps both in the dark and under illumination. A solar simulator with a xenon lamp (from Newport, Model 67005) was used as the light source to measure the efficiency. The devices were illuminated from the composite electrode side at an intensity of approximately 100 mW/cm², measured using an NREL (National Renewable Energy Laboratory) calibrated Hamamatsu mono-crystalline Si cell. Incident photon-to-current efficiency (IPCE) measurements were carried out by illuminating single wavelength light on the cells from an Oriel Monochromator (74001).

The light absorbing sensitizer loading on the composite electrode materials were measured by performing a dye loading experiment, as follows. The composite materials were prepared and their masses were measured. The composites were then soaked in a dye solution of 0.5 mM N-719 dyes in a mixture of acetonitrile and tert-butyl alcohol (1:1 volume ratio), at room temperature for 48 hours. After dye attachment, the composites were washed and dried. For example, the composites can be washed with ethanol and then dried by compressed nitrogen. The attached dye on a nanofiber/nanoparticle composite was desorbed into 0.1 M NaOH and ethanol solution at a 1:1 ratio by volume. The concentration of desorbed dye from the composite was then determined by measuring the UV-visible spectra of the dye solution desorbed from the composite using a UV-visible spectrometer (Agilent 8453) and then applying Beer-Lambert Law as below:

c=A/(εl) (2)

Where A is the absorbance, ε is the extinction coefficient, and l is the pathlength of the solution sample. The mole amount of the dye desorbed was then calculated:

M=cV (3)

where V is the volume of the NaOH and ethanol mixture solution. The mole amount per gram of TiO₂ was calculated as:

t=M/m (4)

where m is the mass of the TiO₂ nanofiber/nanoparticle composite. By combining the above equations, the mole amount of dye per gram of TiO₂ nanofiber/nanoparticle composite was obtained as:

t=AV/(εlm). (5)

To determine the extinction coefficient (ε), absorbance of UV-Vis at various known concentrations of N-719 dye in the solution of NaOH and ethanol (1:1 ratio by volume) was measured. The extinction coefficient, ε, was calculated to be 11.82 mM⁻¹cm⁻¹ at a wavelength of 512 nm using Beer-Lambert Law.

### Result and Analysis:

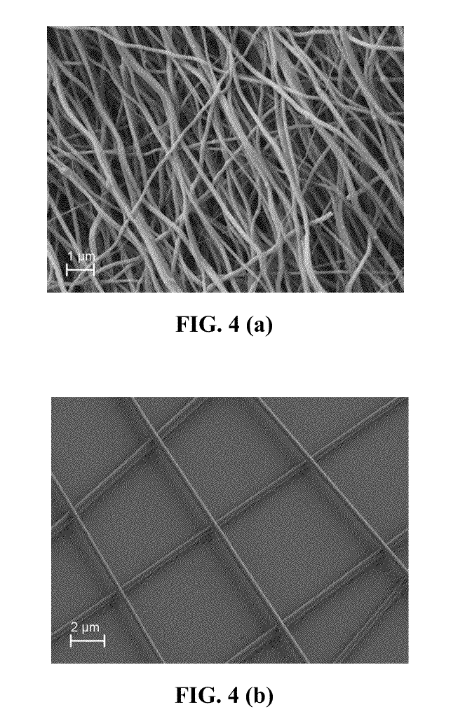

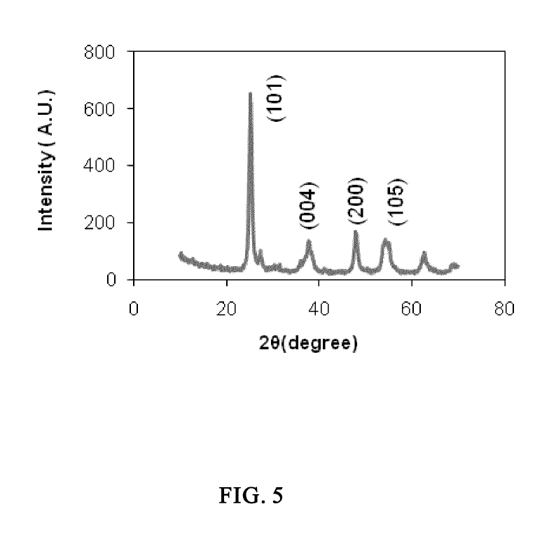

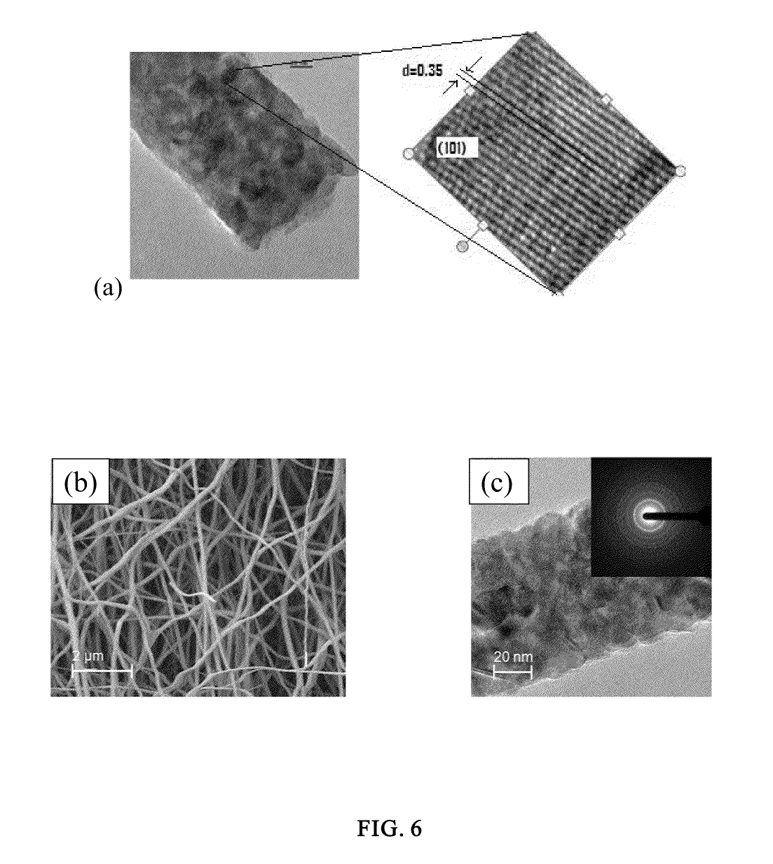

FIG. 4 shows an SEM image of the electrospun fibers having both non-ordered (FIG. 4 (a)) and ordered (FIG. 4 (b)) patterns. The fibers were interconnected and had average diameters larger than 200 nm and lengths of up to several of tens of microns. FIG. 5 is an x-ray diffraction pattern of the electrospun TiO₂ nanofibers. Sharp peaks in the diffraction pattern indicate high crystallinity and anatase phase TiO₂ crystals. FIG. 6(a) is a HRTEM image of a nanofiber at a broken end exhibiting the polycrystalline nature of the nanofiber with nanoscale (e.g., having average grain sizes of about 5 to 20 nm) TiO₂ single crystals compacted together. The HRTEM image showing an interplanar spacing (d) of 0.35 nm further confirmed the anatase form of the TiO₂ crystals with crystal sizes of approximately 10 nm. The anatase phase of TiO₂ can exhibit higher photovoltaic performance than the rutile phase. The anatase TiO₂-based film also has a larger surface area and faster electron transport capability than a rutile TiO₂-based film.

FIG. 6(b) shows SEM images of electrospun TiO₂ nanofibers having average diameters of about 200 to 300 nm and lengths of at least 10 microns. The nanofiber with a diameter of about 100 nm is shown in FIG. 6(c) was one of the thinnest nanofibers identified during TEM examination, it was selected because the electron beam could readily penetrate the nanofiber revealing the detailed morphological structure.

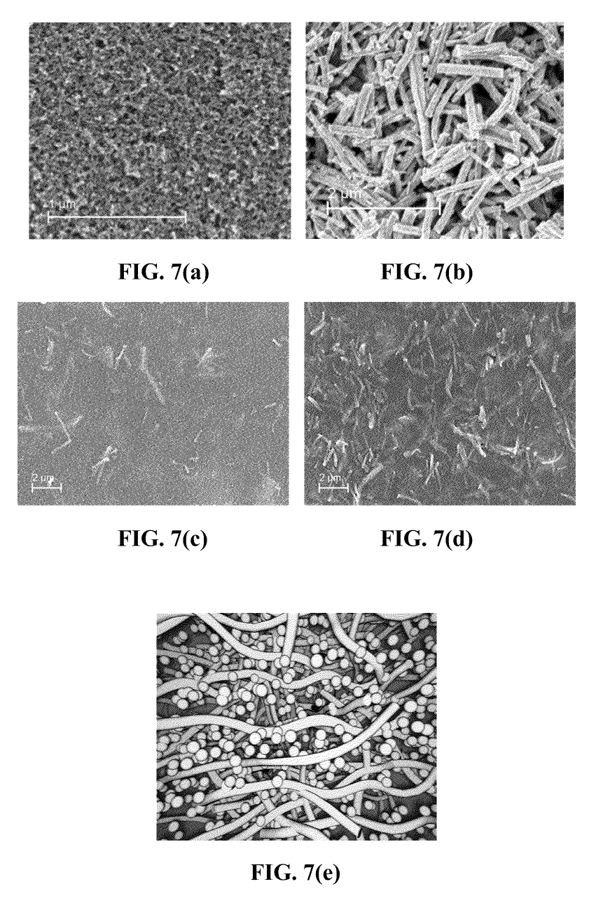

FIGS. 7 (a) and (b) show top view SEM images of TiO₂ films made from TiO₂ nanoparticles and TiO₂ nanofibers, respectively. The nanofibers, which were originally several microns long, were broken to a size ranging from submicrons to micron due to sonication of the nanofibers before deposition onto the FTO. The nanofibers were loosely packed with large spaces between them. Hence, the surface area of the nanofiber-only film is smaller than that of the TiO₂ nanoparticle-only film. FIGS. 7 (c) and (d) are the top view SEM images of the composite photoanodes with 15 wt. % and 50 wt. % nanofibers in the TiO₂ nanoparticle matrix. It can be seen that the 15 wt. % composite had fewer nanofibers embedded in the nanoparticle matrix than the 50 wt. % nanofiber composite. A schematic representation of an electrospun TiO₂ nanofiber embedded in TiO₂ nanoparticles are shown in FIG. 7 (e).

The surface area and dye attachment of the nanofiber/nanoparticle composites having different ratios of nanofibers was also studied. The results are shown in Table 2, below. It was observed that 15 wt. % nanofibers in a nanoparticle matrix was an optimal ratio, exhibiting increased charge transport and improved light harvesting, and a substantially negligible loss of surface area compared to the nanoparticle-only TiO₂ film.

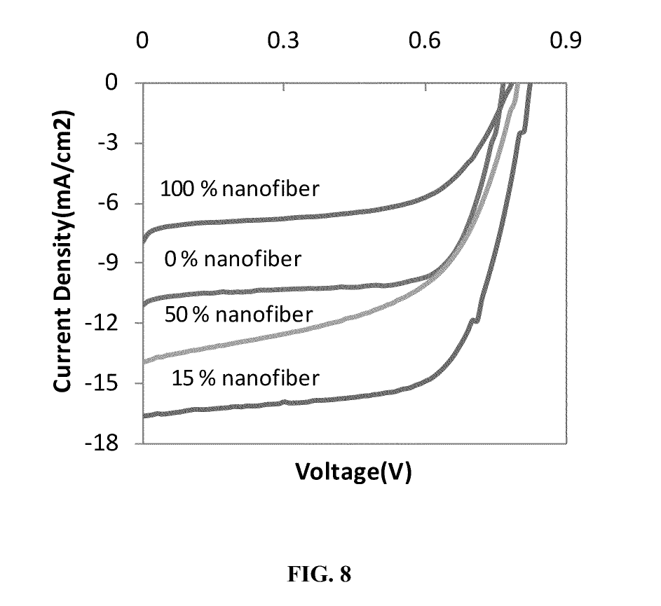

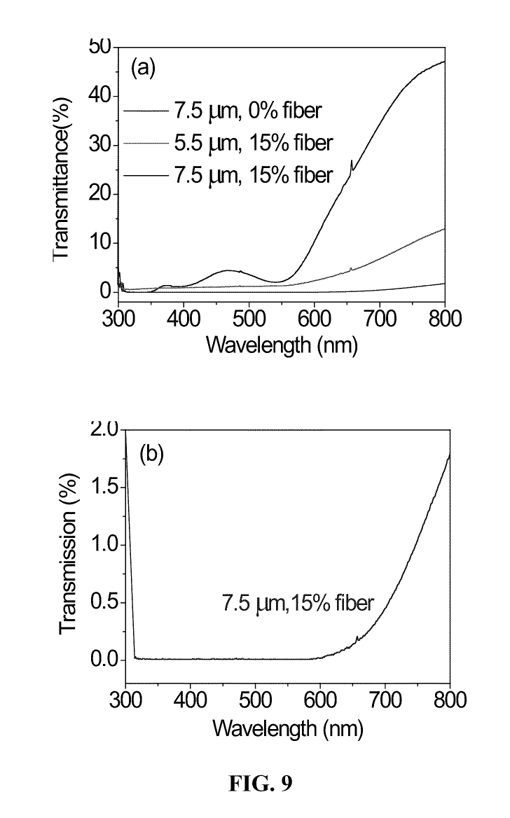

The current density-voltage (J-V) curves in FIG. 8 show the DSSC photovoltaic performance of a set of DSSCs having the following wt. % of nanofibers based on the total weight of the nanofibers and nanoparticles: 0%, 15%, 50%, and 100%. The former three had an active cell area of 0.087 cm², while the 100% nanofiber has an area of 0.27 cm². The 15 wt. % nanofiber cells showed the highest short circuit current, J_{sc}, (16.6 mA/cm²) and energy conversion efficiency, η, (9.1%). This is almost a 25% improvement over the 0 wt. % nanofiber (nanoparticle-only) DSSC. The nanoparticle-only devices showed a current density and efficiency of 13.8 mA/cm² and 7.3%, respectively. FIG. 9 shows that the transmission spectra of the visible and near infrared light (300-800 nm) was significantly reduced by using 15% by weight of nanofibers with a diameter of 200-300 nm with a photoanode thickness of ˜7.5 μm. This demonstrates that nanofibers are much better than nanowires at light harvesting because of their large diameter size.

Composite electrode materials having a nanofiber content above 15 wt. % were also studied and their cell performances were found to decrease with increasing nanofiber content. The performance of DSSCs having composite electrodes with different nanofiber contents are summarized in Table 3.

The decrease in performance is likely because the loss of surface area becomes more significant as the nanofiber content increases beyond 15 wt. %, which will cause the reduction of dye attachment. Consequently, the improvement of charge transport and optical path could not compensate for the loss of the dye attachment with a nanofiber content above 15 wt. %. This was further confirmed in studies of a DSSC based on a nanofiber-only composite electrode, which showed an energy conversion efficiency of only about 3.4%. As shown in Table 2, if the nanofiber percentage was increased to 50 wt. % or more, however, the dye uptake may be reduced by more than 30 wt. %. If the photoanode was made of nanofibers alone, then the dye uptake may be reduced by ˜75 wt. %.

TABLE 2
Dye attachment vs. nanofiber ratio percentage.

| | | Reduction of dye |
|---|---|---|
| Nanofiber (%) | Dye/TiO₂ (10⁻⁶ mol/g) | attachment (%) |
| 0 | 123.50 | 0 |
| 15 | 115.87 | 6.17 |
| 50 | 89.29 | 27.69 |
| 100 | 30.49 | 75.31 |

TABLE 3
Comparison of the cell (cell area = 0.087 cm²) photovoltaic
performance of DSSCs having different nanofiber contents.

| Nanofiber Content | Jsc | Voc | Fill Factor | η |
|---|---|---|---|---|
| (wt. %) | (mA/cm 2) | (V) | (FF) | (%) |
| 0 | 13.78 | 0.76 | 0.70 | 7.3 |
| 15 | 16.63 | 0.82 | 0.67 | 9.1 |
| 50 | 14.25 | 0.79 | 0.58 | 6.5 |
| 100 | 7.94 | 0.78 | 0.55 | 3.4 |

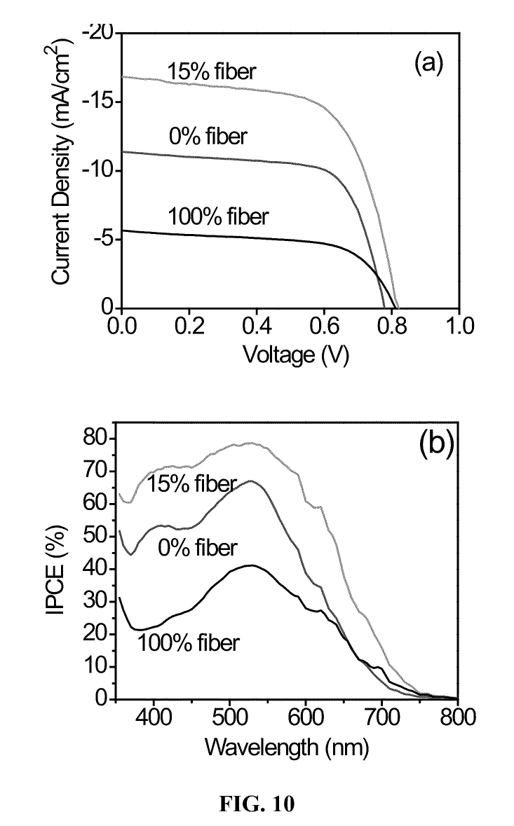

For a second set of cells with an active area of 0.16 cm², the DSSC made using a composite with 15 wt. % fibers achieved a short-circuit current density (J_{sc}) of 16.8 mA cm⁻² and an energy conversion efficiency (h) of 8.8% (FIG. 10 and Table 4). In comparison, a DSSC made using the TiO₂ nanoparticles alone had J_{sc} and η values of 11.4 mA cm⁻² and 6.1%, respectively, for the same photoanode thickness (˜7.5 μm). These results indicate that the 44% improvement in η mainly resulted from the 48% increase in J_{sc}. The increase in J_{sc} is probably due to the light scattering caused by the nanofibers and good dye uptake. Therefore, based on the two sets of nanoparticle/nanofiber DSSCs, the overall increase in cell efficiency is about 25-44% for a 15 wt. % nanofiber composite compared to that in nanoparticle-only DSSCs. However, when the DSSC was made using TiO₂ nanofibers alone as the photoanode, the overall performance was low due to the reduction in dye uptake (FIG. 10, Tables 2 and 4).

TABLE 4
Photovoltaic performance of the DSSCs (cell area = 0.16
cm²) with photoanodes containing various percentages of nanofibers

| Nanofiber | | | | |
|---|---|---|---|---|
| Percentage (wt %) | J_{sc}/mA cm⁻² | V_{oc}/V | Fill factor | η (%) |
| 0 | 11.4 | 0.77 | 0.7 | 6.1 |
| 15 | 16.8 | 0.82 | 0.64 | 8.8 |
| 100 | 5.7 | 0.81 | 0.63 | 2.9 |

When the thickness of the composite was ˜5.5 μm, there was still some transmission in the spectral region 300-800 nm. Once the thickness increased to ˜7.5 μm, the transmission was significantly suppressed (FIG. 9(a)), indicating that a thickness of ˜7.5 μm is greater than necessary for harvesting light in the 300-600 nm region. However, this is just an effective thickness for absorbing long-wavelength light in the 600-800 nm region. Since the dye absorption becomes weaker as the wavelength of the incident light increases, and the light penetration depth (8) becomes larger, in order to harvest more light in the long-wavelength region, a composite of thickness equal to the depth of light penetration (˜7.5 μm) at an average wavelength of 690-700 nm was used. FIG. 9(b) shows that only a tiny percentage (<2%) of light was transmitted in the long-wavelength region for the ˜7.5 μm thick 15% nanofiber film, suggesting that this might be an effective thickness for high-efficiency DSSCs. However a photoanode with a thickness larger than ˜7.5 μm may be desirable for dyes with lower absorption coefficient and wavelengths longer than 800 nm.

The DSSC with the 100% nanofiber photoanode did not have a higher IPCE value at wavelengths longer than 600 nm, even though the long-wavelength region showed the stronger scattering for nanofiber ratios of 15% and larger (such as 100%). When 100% nanofibers were used to make the photoanode the surface area for dye attachment decreased substantially by 75.31% (Table 2). In the 600-800 nm region, the stronger scattering increased light absorption by up to 50% (FIG. 9), which does not compensate for the reduction in dye attachment by 75.31%, thereby leading to a lower IPCE for the photoanode made of 100% nanofibers. It was also found that the V_{oc} of the DSSC with 15% nanofibers was slightly higher than that of the device with 100% nanofibers, while the latter had a higher V_{oc} than the DSSC based on TiO₂ nanoparticles alone. To study the reason for the improved V_{oc}, J-V curves were fitted using the ivfit program assuming a value of n=1.675, where n is the ideality factor and is obtained from the device with nanoparticles only. The fitting results, including dark saturated current density (J₀), series resistance (Rₛₑ), shunt resistance (Rₛₕ), and calculated V_{oc} are shown in Table 5. The calculated V_{oc} values were obtained via the following equation:

$${V}_{oc} = \frac{nk T}{q} ln ( \frac{{J}_{L}}{{J}_{0}} + 1 ) \approx \frac{nk T}{q} ln ( \frac{{J}_{L}}{{J}_{0}} )$$

where k is the Boltzmann constant, T is the temperature, q is the elementary charge, and J_{L} is the current density for the illuminated device. The calculated V_{oc} values for the three different samples were consistent with the respective experimental results in Table 4. Jₒ and Rₛₕ could be indicators of leakage or recombination at the nanofiber-dye-electrolyte interface. Since J₀ was only slightly lower, while Rₛₕ was much smaller in the DSSC with 15% nanofibers, the increased V_{oc} could not be attributed to the reduced recombination; instead, it was mainly caused by the significant increase in J_{L}, originating from the enhancement of light scattering. In contrast to the film with 15% nanofibers, the V_{oc} improvement for the film consisting of 100% nanofibers could not be attributed to enhancement of absorbed light intensity because there was insufficient dye attachment, even though the Mie scattering was stronger. This was possibly caused by the reduction in J₀ and increase in Rₛₕ. In addition, the lower fill factor of the 15% nanofiber photoanodes can be attributed to the smaller Rₛₕ, while that of the 100% nanofiber sample was attributed to the larger Rₛₑ.

TABLE 5
Fitting results for dark saturated current density (J₀) series resistance
(Rₛₑ), shunt resistance (Rₛₕ), and calculated values for V_{oc}

| Nanofiber | | | | Calculated |
|---|---|---|---|---|
| Percentage (wt %) | J₀/A cm⁻² | Rₛₑ/Ωcm² | Rₛₕ/Ωcm² | V_{oc}/V |
| 0 | 1.35 × 10⁻¹⁰ | 4.33 | 650 | 0.778 |
| 15 | 8.86 × 10⁻¹¹ | 4.77 | 374 | 0.818 |
| 100 | 3.20 × 10⁻¹¹ | 7.49 | 704 | 0.815 |

As used herein, and unless otherwise specified, “a” or “an” means “one or more.” All patents, applications, references, and publications cited herein are incorporated by reference in their entirety to the same extent as if they were individually incorporated by reference.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art, all language such as “up to,” “at least,” “greater than,” “less than,” and the like includes the number recited and refers to ranges which can be subsequently broken down into subranges as discussed above. Finally, as will be understood by one skilled in the art, a range includes each individual member.

It is specifically intended that the present invention not be limited to the embodiments and illustrations contained herein, but include modified forms of those embodiments including portions of the embodiments and combinations of elements of different embodiments as come within the scope of the following claims.

We claim:

1. A composition comprising:
(a) a nanoparticle matrix comprising a plurality of semiconductor nanoparticles; and
(b) a plurality of semiconductor nanofibers dispersed in the nanoparticle matrix, the plurality of nanofibers having an average diameter of at least 200 nm and an average length of at least 500 nm.

2. The composition of claim 1 further comprising a light absorbing material attached to at least some of the nanoparticles and nanofibers.

3. The composition of claim 1, wherein the nanofibers have an average length of at least 1 μm.

4. The composition of claim 1, wherein the semiconductor nanoparticles are TiO₂ nanoparticles and the semiconductor nanofibers are TiO₂ nanofibers.

5. The composition of claim 4, comprising from 10 to 20 weight percent TiO₂ nanofibers, based on the total weight of the TiO₂ nanofibers and TiO₂ nanoparticles.

6. The composition of claim 4, comprising no greater than 10 weight percent TiO₂ nanofibers having a diameter of 100 nm or lower.

7. The composition of claim 4, wherein the average diameter of the TiO₂ nanofibers is in the range from 200 to 300 nm.

8. A dye-sensitized solar cell comprising:
(a) a first electrode comprising a composite electrode material comprising:
(i) a nanoparticle matrix comprising a plurality of semiconductor nanoparticles;
(ii) a plurality of semiconductor nanofibers dispersed in the nanoparticle matrix, the plurality of nanofibers having an average diameter of at least 200 nm and an average length of at least 500 nm; and
(iii) a light absorbing material attached to at least some of the semiconductor nanoparticles and semiconductor nanofibers;
(b) a second electrode; and
(c) an electrolyte layer separating the first and second electrodes.

9. The solar cell of claim 8, wherein the semiconductor nanoparticles are TiO₂ nanoparticles and the semiconductor nanofibers are TiO₂ nanofibers.

10. The solar cell of claim 9, wherein the composite electrode material comprises no greater than 10 weight percent TiO₂ nanofibers having a diameter of 100 nm or lower.

11. The solar cell of claim 9, wherein the average diameter of the TiO₂ nanofibers is in the range from 200 to 300 nm.

12. The solar cell of claim 9 having a conversion efficiency of at least 8 percent.

13. The solar cell of claim 9, wherein the composite electrode material comprises from 10 to 20 weight percent TiO₂ nanofibers, based on the total weight of the TiO₂ nanofibers and TiO₂ nanoparticles.

14. The solar cell of claim 8, wherein the nanofibers have an average length of at least 1 μm.

15. A method of making a composite electrode material, the method comprising:
(a) dispersing a plurality of semiconductor nanofibers in a paste comprising semiconductor nanoparticles to provide a composite paste, the semiconductor nanofibers having an average diameter of at least 200 nm and an average length of at least 500 nm;
(b) sintering the composite paste to provide a composite film; and
(c) sensitizing the composite film with a light absorbing material.

16. The method of claim 15, wherein the semiconductor nanoparticles are TiO₂ nanoparticles and the semiconductor nanofibers are TiO₂ nanofibers.

17. The method of claim 16, wherein the TiO₂ nanofibers are formed by an electrospinning.

18. The method of claim 17, wherein the composite electrode material comprises no greater than 10 weight percent TiO₂ nanofibers having a diameter of 100 nm or lower.

19. The method of claim 17, wherein the average diameter of the TiO₂ nanofibers is in the range from 200 to 300 nm.

20. The method of claim 17, wherein the nanofibers have an average length of at least 1 μm.
